(19) United States
(12) Patent Application Publication
(10) Pub. No.: US 2025/0372154 A1
(43) Pub. Date: Dec. 4, 2025

(54) SEMICONDUCTOR DEVICE HAVING INPUT BUFFER CIRCUIT

(71) Applicant: MICRON TECHNOLOGY, INC., Boise, ID (US)

(72) Inventors: Shun Nishimura, Kanagawa (JP); Hiroyuki Matsuno, Tokyo (JP)

(73) Assignee: MICRON TECHNOLOGY, INC., Boise, ID (US)

(21) Appl. No.: 19/216,420

(22) Filed: May 22, 2025

Related U.S. Application Data
(60) Provisional application No. 63/655,290, filed on Jun. 3, 2024.

(51) Int. Cl. G11C 11/4093

(52) U.S. Cl. CPC G11C 11/4093

(57) ABSTRACT

An example apparatus includes: first and second inverters cross-coupled to each other, a first transistor coupled between the first and third circuit nodes; a second transistor coupled between the second and fourth circuit nodes; a plurality of third transistors coupled in parallel between the third circuit node and the second power line; and a plurality of fourth transistors coupled in parallel between the fourth circuit node and the second power line. When the control code signal indicates a first value: at least one of the plurality of third transistors is brought into an OFF state; remaining one or ones of the plurality of third transistors are brought into an ON state; at least one of the plurality of fourth transistors is brought into an OFF state; and remaining one or ones of the plurality of fourth transistors are brought into an ON state.

### CROSS-REFERENCE TO RELATED APPLICATIONS

This application claims the filing benefit of U.S. Provisional Application No. 63/655,290, filed Jun. 3, 2024. This application is incorporated by reference herein in its entirety and for all purposes.

### BACKGROUND

There is a case where an input buffer of differential input type that compares the level of an input signal and the level of a reference potential is used for a semiconductor device such as a DRAM. In such an input buffer of differential input type, characteristics of a transistor constituting a circuit on an input side and characteristics of another transistor constituting a circuit on a reference side are required to match each other.

### BRIEF DESCRIPTION OF THE DRAWINGS

FIG. 1 is a block diagram showing a configuration of a semiconductor memory device according to an embodiment of the present disclosure;

FIG. 2 is a block diagram showing a configuration of main components of a data control circuit;

FIG. 3 is a circuit diagram of a data latch circuit;

FIGS. 4A to 4C are circuit diagrams of decoder circuits;

FIG. 5A is a truth table of the decoder circuits;

FIG. 5B is a truth table representing relationships among reference examples of a control code signal, a down-code signal, and an up-code signal; and

FIG. 6 is a table representing adjustment amounts of input offsets for respective taps.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

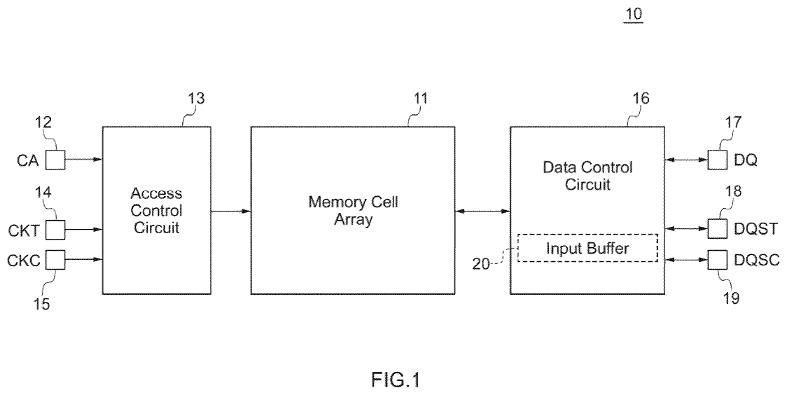

FIG. 1 is a block diagram showing a configuration of a semiconductor memory device 10 according to an embodiment of the present disclosure. The semiconductor memory device 10 shown in FIG. 1 is an LPDDR5 DRAM and includes a memory cell array 11. When access is made to the memory cell array 11, a command address signal CA is input to a command address terminal 12 from outside. The command address signal CA is supplied to an access control circuit 13. The access control circuit 13 synchronizes with complementary clock signals CKT and CKC respectively input to clock terminals 14 and 15, thereby decoding the command address signal CA, counting latencies, and the like.

When a command included in the command address signal CA indicates a read operation, the access control circuit 13 makes read-access to a memory cell included in the memory cell array 11 based on an address included in the command address signal CA. Read data DQ read from the accessed memory cell is output to outside from a data I/O terminal 17 via a data control circuit 16. When the command included in the command address signal CA indicates a write operation, write data DQ input to the data I/O terminal 17 is transferred to the memory cell array 11 via an input buffer circuit 20 included in the data control circuit 16. The write data DQ is input to the memory cell array 11 as it synchronizes with complementary data strobe signals DQST and DQSC respectively supplied to data strobe terminals 18 and 19. The write data DQ having been transferred to the memory cell array 11 is written in the memory cell included in the memory cell array 11 based on the address included in the command address signal CA.

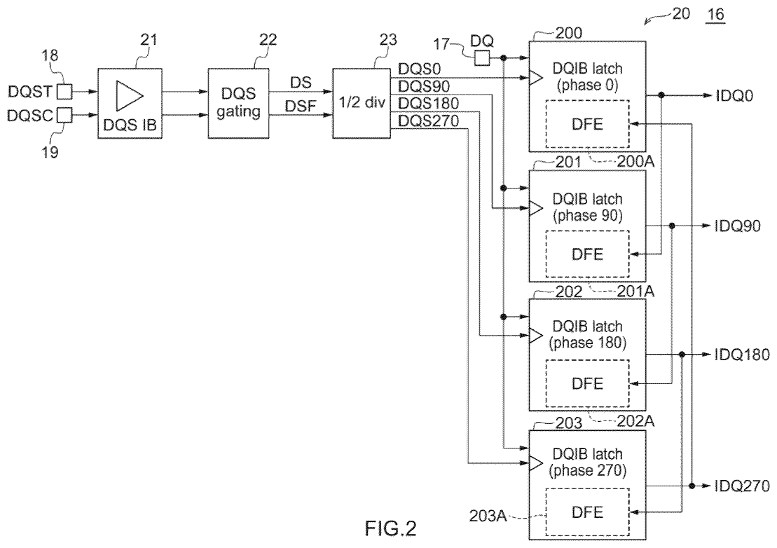

FIG. 2 is a block diagram showing a configuration of main components of the data control circuit 16. As shown in FIG. 2, the data control circuit 16 includes a gating circuit 22 that receives data strobe signals DQST and DQSC via an input buffer 21. Internal data strobe signals DS and DSF output from the gating circuit 22 respectively correspond to the data strobe signals DQST and DQSC. The internal data strobe signals DS and DSF are input to a dividing circuit 23. The dividing circuit 23 generates four-phase internal data strobe signals DQS0, DQS90, DQS180, and DQS270 by dividing the internal data strobe signals DS and DSF. When the phase of the internal data strobe signal DQS0 is 0°, the phases of the internal data strobe signals DQS90, DQS180, and DQS270 are 90°, 180°, and 270°, respectively. The internal data strobe signals DQS0, DQS90, DQS180, and DQS270 are supplied to the input buffer 20.

The input buffer 20 includes a data latch circuit 200 that synchronizes with the internal data strobe signal DQS0 to latch the write data DQ, a data latch circuit 201 that synchronizes with the internal data strobe signal DQS90 to latch the write data DQ, a data latch circuit 202 that synchronizes with the internal data strobe signal DQS180 to latch the write data DQ, and a data latch circuit 203 that synchronizes with the internal data strobe signal DQS270 to latch the write data DQ. Write data IDQ0, write data IDQ90, write data IDQ180, and write data IDQ270 respectively latched on the data latch circuits 200 to 203 are transferred to the memory cell array 11.

The data latch circuits 200, 201, 202, and 203 respectively include a DFE (Decision Feedback Equalizer) circuit 200A, a DFE circuit 201A, a DFE circuit 202A, and a DFE circuit 203A each of which reduces ISI (Intersymbol Interference) noise. Data latched on the data latch circuit 200 is fed back to the DFE circuit 201A included in the data latch circuit 201. Data latched on the data latch circuit 201 is fed back to the DFE circuit 202A included in the data latch circuit 202. Data latched on the data latch circuit 202 is fed back to the DFE circuit 203A included in the data latch circuit 203. Data latched on the data latch circuit 203 is fed back to the DFE circuit 200A included in the data latch circuit 200.

In this manner, four data latch circuits 200 to 203 are allocated to one data I/O terminal 17. While only one data I/O terminal 17 is shown in FIGS. 1 and 2, a plurality (eight, for example) of data I/O terminals 17 are provided in practice, and four data latch circuits 200 to 203 are allocated to each of the data I/O terminals 17.

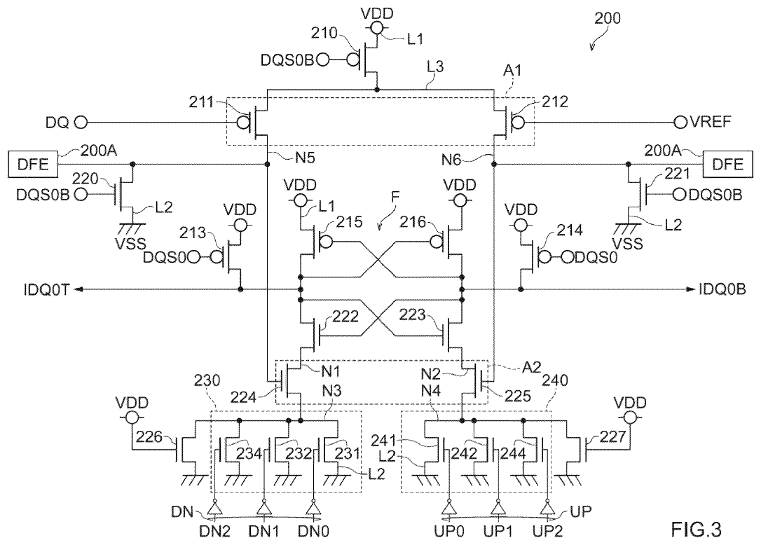

FIG. 3 is a circuit diagram of the data latch circuit 200. As shown in FIG. 3, the data latch circuit 200 includes P-channel MOS transistors 210 to 216, N-channel MOS transistors 220 to 227, and current control circuits 230 and 240. The transistor 210 is coupled between a power line L1 supplied with a power potential VDD and a common source line L3. An inversion signal DQS0B of the internal data strobe signal DQS0 is input to a gate electrode of the transistor 210. The transistor 211 is coupled between the common source line L3 and a circuit node N5. The write data DQ is input from outside to a gate electrode of the transistor 211 via the data I/O terminal 17. The transistor 212 is coupled between the common source line L3 and a circuit node N6. A reference potential VREF is supplied to a gate electrode of the transistor 212. The transistors 211 and 212 constitute a differential amplifier circuit A1 that controls the amount of current flowing into the circuit nodes N5 and N6 based on a potential difference between the reference potential VREF and the write data DQ. The differential amplifier circuit A1 is activated when the inversion signal DQS0B of the internal data strobe signal DQS0 becomes a low level. The transistor 220 is coupled between the circuit node N5 and a power line L2 supplied with a ground potential VSS. A transistor 221 is coupled between the circuit node N6 and the power line L2 supplied with the ground potential VSS. The inversion signal DQS0B of the internal data strobe signal DQS0 is input to gate electrodes of the transistors 220 and 221. With this configuration, when the inversion signal DQS0B of the internal data strobe signal DQS0 becomes a high level, the circuit nodes N5 and N6 are precharged on the ground potential VSS and an amplifier circuit A1 is inactivated. Further, the DFE circuit 200A is coupled to each of the circuit nodes N5 and N6.

The transistors 215, 216, 222, and 223 constitute a flip-flop circuit F. That is, the transistors 215 and 222 are coupled in series between the power line L1 supplied with the power potential VDD and a circuit node N1, and gate electrodes thereof are coupled in common to drains of the transistors 216 and 223. The circuit node N1 constitutes one input node of the flip-flop circuit F. The transistors 216 and 223 are coupled in series between the power line L1 supplied with the power potential VDD and a circuit node N2, and gate electrodes thereof are coupled in common to drains of the transistors 215 and 222. The circuit node N2 constitutes the other input node of the flip-flop circuit F. Internal write data IDQ0T is output from the drains of the transistors 215 and 222 constituting one output node. Internal write data IDQ0B is output from the drains of the transistors 216 and 223 constituting the other output node. When the internal data strobe signal DQS0 becomes a low level, internal write data IDQ0T/B is precharged on the power potential VDD by the transistors 213 and 214.

The transistor 224 is coupled between the circuit node N1 and a circuit node N3. A gate electrode of the transistor 224 is coupled to the circuit node N5. The circuit node N3 is coupled to the power line L2 supplied with the ground potential VSS via the current control circuit 230 and a transistor 226. A transistor 225 is coupled between the circuit node N2 and a circuit node N4. A gate electrode of the transistor 225 is coupled to the circuit node N6. The circuit node N4 is coupled to the power line L2 supplied with the ground potential VSS via the current control circuit 240 and the transistor 227. With this configuration, the transistors 224 and 225 constitute an amplifier circuit A2 that supplies an operating current to the flip-flop circuit F based on the potentials of the circuit nodes N5 and N6.

The current control circuit 230 is formed of transistors 231, 232, and 234 that are coupled in parallel between the circuit node N3 and the power line L2 supplied with the ground potential VSS. Inversion signals of each of bits DN0, DN1, and DN2 constituting a down-code signal DN are respectively input to gate electrodes of the transistors 231, 232, and 234. The down-code signal DN is a signal in binary form. The bit DN0 is a least significant bit of the down-code signal DN and the transistor 231 input with an inversion signal of the bit DN0 constitutes a least significant transistor. The bit DN2 is a most significant bit of the down-code signal DN and the transistor 234 input with an inversion signal of the bit DN2 constitutes a most significant transistor. Here, when the transistor size of the transistor 231 is set as “1”, the transistor size of the transistor 232 is “2” and the transistor size of the transistor 234 is “4”. Further, the transistor 226 is coupled in parallel to the current control circuit 230. Since the power potential VDD is applied to a gate electrode of the transistor 226 in a fixed manner, the transistor 226 is turned ON regardless of the down-code signal DN.

The current control circuit 240 is formed of transistors 241, 242, and 244 that are coupled in parallel between the circuit node N4 and the power line L2 supplied with the ground potential VSS. Inversion signals of each of bits UP0, UP1, and UP2 constituting an up-code signal UP are respectively input to gate electrodes of the transistors 241, 242, and 244. The up-code signal UP is a signal in binary form. The bit UP0 is a least significant bit of the up-code signal UP and the transistor 241 input with an inversion signal of the bit UP0 constitutes a least significant transistor. The bit UP2 is a most significant bit of the up-code signal UP and the transistor 244 input with an inversion signal of the bit UP2 constitutes a most significant transistor. Here, when the transistor size of the transistor 241 is set as “1”, the transistor size of the transistor 242 is “2” and the transistor size of the transistor 244 is “4”. Further, the transistor 227 is coupled in parallel to the current control circuit 240. Since the power potential VDD is applied to a gate electrode of the transistor 227 in a fixed manner, the transistor 227 is turned ON regardless of the up-code signal UP.

Here, the sizes of the transistor 231 and the transistor 241 are mutually the same. The sizes of the transistor 232 and the transistor 242 are mutually the same. The sizes of the transistor 234 and the transistor 244 are mutually the same. The sizes of the transistor 226 and the transistor 227 are mutually the same.

With such a circuit configuration, the amount of current flowing into the current control circuit 230 according to the down-code signal DN can be adjusted. Similarly, the amount of current flowing into the current control circuit 240 can be adjusted according to the up-code signal UP. Accordingly, when there is an input offset in the data latch circuit 200, by adjusting the amount of current flowing into the current control circuits 230 and 240 using the down-code signal DN and the up-code signal UP, the input offset can be cancelled.

Each of other data latch circuits 201 to 203 constituting the input buffer 20 has a circuit configuration identical to that of the data latch circuit 200 shown in FIG. 3. Mutually different down-code signals DN and up-code signals UP are used for each of the data latch circuits 200 to 203, and thus each input offset in the data latch circuits 200 to 203 is cancelled in each of these circuits.

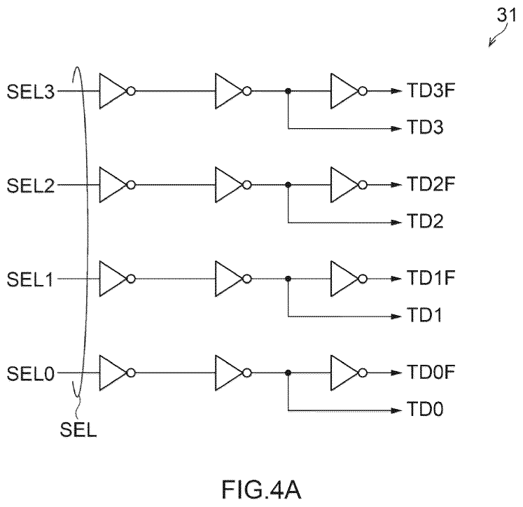

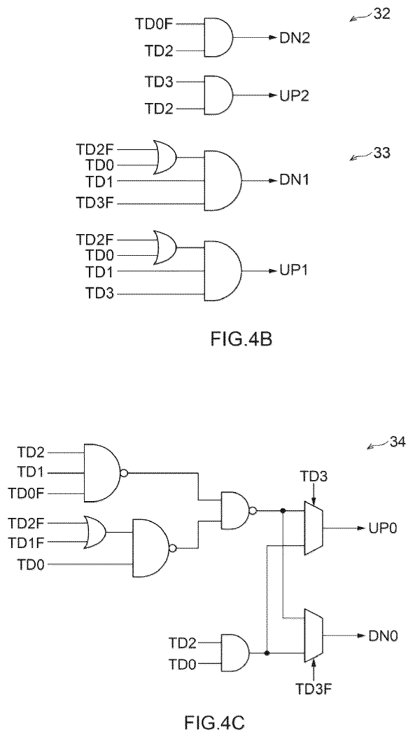

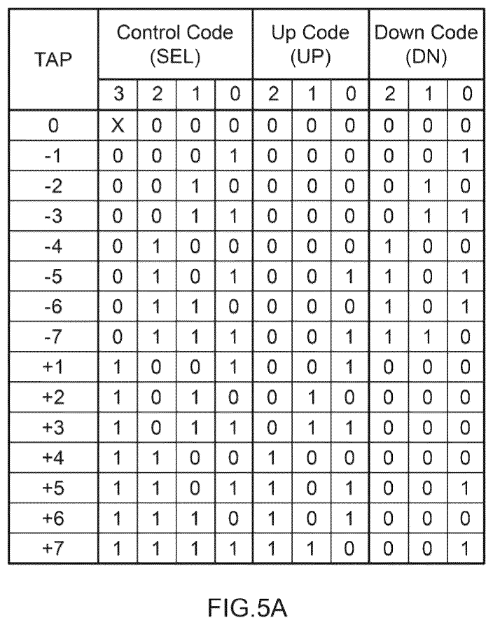

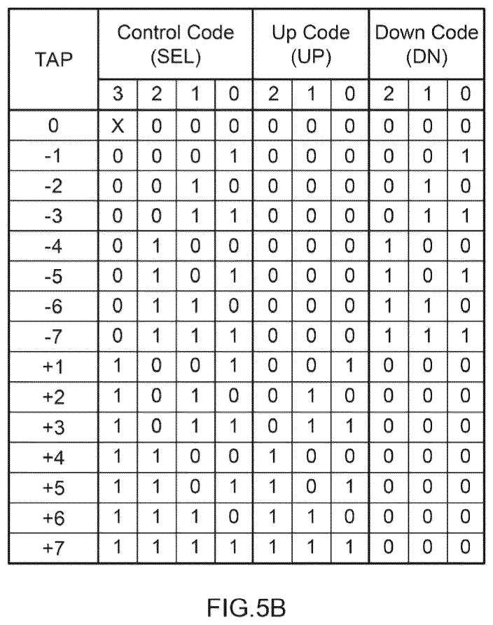

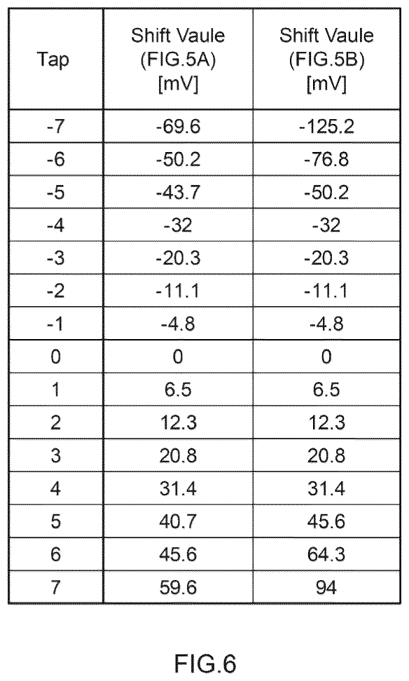

FIGS. 4A to 4C are circuit diagrams of decoder circuits that generate the down-code signal DN and the up-code signal UP. FIG. 5A is a truth table of the decoder circuits shown in FIGS. 4A to 4C.

As shown in FIGS. 4A to 4C and FIG. 5A, the down-code signal DN and the up-code signal UP are generated by decoding a control code signal SEL. The control code signal SEL is a 4-bit binary signal formed of bits SEL0 to SEL3. Here, a circuit 31 shown in FIG. 4A is a circuit that generates intermediate signals TD0 to TD3 and TD0F to TD3F from the control code signal SEL. A circuit 32 shown in FIG. 4B is a circuit that generates the bit DN2 of the down-code signal DN and the bit UP2 of the up-code signal UP from the intermediate signals TD0 to TD3 and TD0F to TD3F. A circuit 33 shown in FIG. 4B is a circuit that generates the bit DN1 of the down-code signal DN and the bit UP1 of the up-code signal UP from the intermediate signals TD0 to TD3 and TD0F to TD3F. A circuit 34 shown in FIG. 4C is a circuit that generates the bit DN0 of the down-code signal DN and the bit UP0 of the up-code signal UP from the intermediate signals TD0 to TD3 and TD0F to TD3F.

In the examples shown in FIGS. 5A and 5B, when the value of the control code signal SEL is “x000” (where x indicates “don't care”), values of adjustment taps of the current control circuits 230 and 240 are 0, and “down-code signal DN<2:0>=000” and “up-code signal UP<2:0>=000” are established. In this case, all of the transistors 231, 232, and 234 constituting the current control circuit 230 are turned ON and the current supply capacity of the current control circuit 230 becomes maximum, and all of the transistors 241, 242, and 244 constituting the current control circuit 240 are turned ON and the current supply capacity of the current control circuit 240 becomes maximum. Meanwhile, when the bit SEL3 as a most significant bit of the control code signal SEL is in a low level, the down-code signal DN<2:0> is changed according to the value of the control code signal SEL<2:0>, so that the current supply capacity of the current control circuit 230 is reduced. On the other hand, when the bit SEL3 as a most significant bit of the control code signal SEL is in a high level, the up-code signal UP<2:0> is changed according to the value of the control code signal SEL<2:0>, so that the current supply capacity of the current control circuit 240 is reduced.

FIG. 5B is a truth table representing relationships among reference examples of the control code signal SEL and the down-code signal DN and the up-code signal UP. In the reference examples shown in FIG. 5B, when the bit SEL3 of the control code signal SEL is in a low level, the value of the control code signal SEL<2:0> and the value of the down-code signal DN<2:0> match each other. Accordingly, when the bit SEL3 of the control code signal SEL is in a low level, as the value of the control code signal SEL<2:0> is incremented by one bit, the value of the down-code signal DN<2:0> is also incremented by one bit. In this case, the value of the up-code signal UP<2:0> is fixed as “000”. Meanwhile, when the bit SEL3 of the control code signal SEL is in a high level, the value of the control code signal SEL<2:0> and the value of the up-code signal UP<2:0> match each other. Accordingly, when the bit SEL3 of the control code signal SEL is in a high level, as the value of the control code signal SEL<2:0> is incremented by one bit, the value of the up-code signal UP<2:0> is also incremented by one bit. In this case, the value of the down-code signal DN<2:0> is fixed as “000”.

On the other hand, as any of the decoder circuits shown in FIGS. 4A to 4C is used, when the bit SEL3 of the control code signal SEL is in a low level, within a range of tap values −1 to −5, the value of the down-code signal DN<2:0> is incremented by one bit as it coordinates with the value of the control code signal SEL<2:0>. However, when the tap value −5 is selected, the value of the up-code signal UP<2:0> becomes “001” and the current supply capacity of the current control circuit 240 is slightly reduced. Further, when the tap value is changed from −5 to −6, the value of the down-code signal DN<2:0> does not change, but the value of the up-code signal UP<2:0> returns to “000” instead. Accordingly, the current supply capacity of the current control circuit 240 becomes maximum. Further, when the tap value is changed from −6 to −7, the value of the down-code signal DN<2:0> is incremented from “101” to “110” and thus the current supply capacity of the current control circuit 230 is further reduced, and the value of the up-code signal UP<2:0> becomes “001” and thus the current supply capacity of the current control circuit 240 is slightly reduced.

Similarly, when the bit SEL3 of the control code signal SEL is in a high level, within a range of tap values +1 to +5, the value of the up-code signal UP<2:0> is incremented by one bit as it coordinates with the value of the control code signal SEL<2:0>. However, when the tap value +5 is selected, the value of the down-code signal DN<2:0> becomes “001” and the current supply capacity of the current control circuit 230 is slightly reduced. Further, when the tap value is changed from +5 to +6, the value of the up-code signal UP<2:0> does not change, but the value of the down-code signal DN<2:0> returns to “000” instead. Accordingly, the current supply capacity of the current control circuit 230 becomes maximum. Further, when the tap value is changed from +6 to +7, the value of the up-code signal UP<2:0> is incremented from “101” to “110” and thus the current supply capacity of the current control circuit 240 is further reduced, and the value of the down-code signal DN<2:0> becomes “001” and thus the current supply capacity of the current control circuit 230 is slightly reduced.

FIG. 6 is a table representing adjustment amounts of input offsets for respective taps. As shown in FIG. 6, when the value of the down-code signal DN<2:0> or the up-code signal UP<2:0> is simply changed according to the value of a control code signal SEL<3:0> as in the control method described with reference to FIG. 5B, as the absolute value of a relevant tap becomes larger, the adjustment amount for one tap is increased. For example, in the control method shown in FIG. 5B, in a case of changing the tap value from −1 to −2, the adjustment amount of input offset is changed by 6.3 mV, whereas in a case of changing the tap value from −6 to −7, the adjustment amount of input offset is changed by 48.4 mV. Accordingly, there occurs a case where fine adjustment of input offset becomes difficult. Such a phenomenon occurs because as the absolute value of a relevant tap becomes larger, the ratio of current flowing into the transistor 226 or the transistor 227 is increased.

On the other hand, according to the control method described with reference to FIG. 5A, in a region where the absolute value of a relevant tap is large, increase of the adjustment amount for one tap is suppressed. For example, in the control method shown in FIG. 5A, in a case of changing the tap value from −1 to −2, the adjustment amount of input offset is changed by 6.3 mV, whereas in a case of changing the tap value from −6 to −7, the adjustment amount of input offset is set to be 19.4 mV. Accordingly, adjustment of input offset can be made more accurately.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
first and second input nodes;
first and second power lines supplied with first and second power potentials different from each other;
a first current path including a first transistor and a first source control circuit coupled in series between the first and second power lines, the first transistor being configured to be controlled responsively to a first signal at the first input node and the first source control circuit having a plurality of second transistors coupled in parallel; and
a second current path including a third transistor and a second source control circuit coupled in series between the first and second power lines, the third transistor being configured to be controlled responsively to a second signal at the second input node and the second source control circuit having a plurality of fourth transistors coupled in parallel;
wherein each of the plurality of second and fourth transistors is configured to be controlled by a control code signal, and
wherein, when the control code signal indicates a first value:
at least one of the plurality of second transistors is brought into an OFF state;
remaining one or ones of the plurality of second transistors are brought into an ON state;
at least one of the plurality of fourth transistors is brought into an OFF state; and
remaining one or ones of the plurality of fourth transistors are brought into an ON state.

2. The apparatus of claim 1, wherein, when the control code signal indicates the first value, a least significant one of the plurality of second transistors is brought into an OFF state.

3. The apparatus of claim 2, wherein, when the control code signal indicates the first value, all of the remaining ones of the plurality of second transistors are brought into an ON state.

4. The apparatus of claim 2, wherein, when the control code signal indicates the first value, a most significant one of the plurality of fourth transistors is brought into an OFF state.

5. The apparatus of claim 4, wherein, when the control code signal indicates a second value different from the first value:
at least one of the plurality of second transistors is brought into an OFF state;
remaining one or ones of the plurality of second transistors are brought into an ON state; and
a least significant one of the plurality of fourth transistors is brought into an OFF state.

6. The apparatus of claim 5, wherein, when the control code signal indicates the second value, all of the remaining ones of the plurality of fourth transistors are brought into an ON state.

7. The apparatus of claim 5, wherein, when the control code signal indicates the second value, a most significant one of the plurality of second transistors is brought into an OFF state.

8. The apparatus of claim 1, wherein, when the control code signal indicates a third value different from the first value, at least one of the plurality of fourth transistors is brought into an OFF state, and all of the plurality of second transistors are brought into an ON state.

9. The apparatus of claim 8, wherein, when the control code signal indicates a fourth value different from the first and third values, at least one of the plurality of second transistors is brought into an OFF state, and all of the plurality of fourth transistors are brought into an ON state.

10. The apparatus of claim 9, wherein, when the control code signal indicates a fifth value different from the first, third, and fourth control values, all of the plurality of second transistors are brought into an ON state, and all of the plurality of fourth transistors are brought into an ON state.

11. The apparatus of claim 1, further comprising a fifth transistor coupled in parallel with the first source control circuit,
wherein the fifth transistor is brought into an ON state regardless of the control code signal.

12. The apparatus of claim 11, further comprising a sixth transistor coupled in parallel with the second source control circuit,
wherein the sixth transistor is brought into an ON state regardless of the control code signal.

13. The apparatus of claim 12,
wherein at least one of the plurality of second transistor is brought into an ON state regardless of the control code signal, and
wherein at least one of the plurality of fourth transistor is brought into an ON state regardless of the control code signal.

14. The apparatus of claim 1, further comprising:
a common source line;
a seventh transistor coupled between the common source line and a control electrode of the first transistor; and
an eighth transistor coupled between the common source line and a control electrode of the third transistor,
wherein the first input node is a control electrode of the seventh transistor supplied with the first signal, and
wherein the second input node is a control electrode of the eighth transistor supplied with the second signal.

15. The apparatus of claim 14, further comprising a ninth transistor coupled between the first power line and the common source line,
wherein the ninth transistor has a control electrode supplied with an internal data strobe signal.

16. The apparatus of claim 1,
wherein the first current path further including fifth and sixth transistors coupled in series between the first power line and the first transistor, the fifth and sixth transistors having a first output node therebetween;
wherein the second current path further including seventh and eighth transistors coupled in series between the first power line and the second transistor, the seventh and eighth transistors having a second output node therebetween,
wherein gates of fifth and sixth transistors are coupled in common to the second output node, and
wherein gates of the seventh and eighth transistors are coupled in common to the first output node.

17. An apparatus comprising:
a first power line supplied with a first power potential;
a second power line supplied with a second power potential different from the first power potential;
a flip-flop circuit coupled to the first power line and having first and second input nodes and first and second output nodes;
a first transistor and a first current control circuit coupled in series between the first input node of the flip-flop circuit and the second power line;
a second transistor and a second current control circuit coupled in series between the second input node of the flip-flop circuit and the second power line;
a third transistor coupled between the first power line and a common source line;
a fourth transistor coupled between the common source line and a control electrode of the first transistor, the fourth transistor having a control electrode supplied with an input signal from outside; and
a fifth transistor coupled between the common source line and a control electrode of the second transistor, the fifth transistor having a control electrode supplied with a reference potential,
wherein each of the first and second current control circuits is configured to be controlled in a driving ability by a control code signal, and
wherein, when the control code is incremented from a first value to a second value, the driving ability of both the first and second current control circuits changes.

18. The apparatus of claim 17,
wherein, when the control code is incremented from the first value to the second value, the driving ability of both the first and second current control circuits decreases, and
wherein, when the control code is incremented from the second value to a third value, the driving ability of the first current control circuit increases.

19. The apparatus of claim 18,
wherein, when the control code is incremented from the second value to the third value, the driving ability of the second current control circuit does not change, and
wherein, when the control code is incremented from the third value to a fourth value, the driving ability of both the first and second current control circuits decreases.

20. An apparatus comprising:
a first power line supplied with a first power potential;
a second power line supplied with a second power potential different from the first power potential;
a flip-flop circuit coupled to the first power line and having first and second input nodes and first and second output nodes;
a first transistor and a first current control circuit coupled in series between the first input node of the latch circuit and the second power line;
a second transistor and a second current control circuit coupled in series between the second input node of the latch circuit and the second power line;
a third transistor coupled between the first power line and a common source line;
a fourth transistor coupled between the common source line and a control electrode of the first transistor, the fourth transistor having a control electrode supplied with an input signal from outside;
a fifth transistor coupled between the common source line and a control electrode of the second transistor, the fifth transistor having a control electrode supplied with a reference potential; and
a decoder circuit configured to generate a first code signal and a second control signal based on a control code signal,
wherein the first current control circuit is configured to be controlled in a driving ability by the first control code,
wherein the second current control circuit is configured to be controlled in a driving ability by the second control code, and
wherein the decoder circuit is configured to:
change the first code signal based on the control code signal without changing the second code signal when a value of the control code signal is within a first range;
change the second code signal based on the control code signal without changing the first code signal when a value of the control code signal is within a second range; and
change both the first and second control code signals based on the control code signal when a value of the control code signal is within a third range.
